(19) United States
(12) Patent Application Publication
(10) Pub. No.: US 2020/0243242 A1
(43) Pub. Date: Jul. 30, 2020

(54) MAGNETIC ELEMENT, MAGNETIC DEVICE, AND MANUFACTURING METHOD OF MAGNETIC ELEMENT

(71) Applicant: THE UNIVERSITY OF TOKYO, Tokyo (JP)

(72) Inventors: Naoya SHIBATA, Tokyo (JP); Takao MATSUMOTO, Tokyo (JP)

(73) Assignee: THE UNIVERSITY OF TOKYO, Tokyo (JP)

(21) Appl. No.: 16/610,118

(22) PCT Filed: May 1, 2018
(86) PCT No.: PCT/JP2018/017423

§ 371 Date: Jan. 9, 2020

Related U.S. Application Data
(60) Provisional application No. 62/500,222, filed on May 2, 2017.

(51) Int. Cl. H01F 10/16; G01R 33/09; G11C 11/16; H01L 43/12

(52) U.S. Cl. CPC H01F 10/16; H01L 43/12; G11C 11/16; G01R 33/091

(57) ABSTRACT

A magnetic element is formed from a magnetic material, which is a material that is capable of generating a magnetic skyrmion, and a defect is introduced at a position corresponding to each side of an approximate triangle in plan view. A magnetic field having such a direction and an intensity as to generate at least one magnetic skyrmion in an area corresponding to inside of the approximate triangle is applied to the magnetic material with the defects introduced therein. This causes the magnetic skyrmion to be generated in the area corresponding to inside of the approximate triangle. This configuration enables the generated magnetic skyrmion to be stably kept at a higher temperature.

This is a national phase application of PCT/JP2018/017423 filed on May 1, 2018, claiming priority to U.S. Patent Application No. 62/500,222 filed on May 2, 2017, the contents of which are incorporated herein by reference.

### TECHNICAL FIELD

The present disclosure relates to a magnetic element, a magnetic device and a manufacturing method of the magnetic element. More specifically, the present disclosure relates to a magnetic element formed from a magnetic material, a magnetic device including a plurality of such magnetic elements, and a manufacturing method of the magnetic element that is formed from the magnetic material.

### BACKGROUND

A proposed configuration of a magnetic element is formed from a magnetic material having a helimagnetic structure (as described in, for example, Patent Literature 1). In this magnetic element, the magnetic material is formed in a plate-like shape. In the state that a constant magnetic field is applied to the magnetic material, the magnetic material is heated to be a higher temperature than 29 K and is then rapidly cooled down to be a lower temperature than 27 K. This causes a magnetic skyrmion to be generated and kept in a metastable manner. The magnetic skyrmion disappears when the magnetic material is heated to be a higher temperature than 27 K.

Furthermore, another proposed configuration of the magnetic element is formed from a magnetic material that is capable of generating the magnetic skyrmion at ambient temperature or is formed from a layered magnetic thin film that is capable of generating the magnetic skyrmion at ambient temperature (as described in, for example, Non-Patent Literature 1 and Non-Patent Literature 2).

### CITED REFERENCE

### Patent Literature

PTL 1: JP2017-41580
Non-PTL 1: Y. Tokunaga, X. Z. Yu, J. S. White, H. M. Ronnow, D. Morikawa, Y. Taguchi and Y. Tokura, A new class of chiral materials hosting magnetic skyrmions beyond room temperature, Nature Communications Vol. 6, 7638 (2015).
Non-PTL 2: W. Legrand, D. Maccariello, N. Reyren, K. Garcia, C. Moutafis, C. Moreau-Luchaire, S. Collin, K. Bouzehouane, V. Cros and A. Fert, Room-Temperature Current-Induced Generation and Motion of sub 100 nm Skyrmions, Nano letters Vol. 17, 2703-2712, May 30, 2017.

### SUMMARY

The magnetic element described in Patent Literature 1, however, fails to stably keep the generated magnetic skyrmion at the temperature higher than 27 K. The magnetic element described in Non-Patent Literature 1 or Non-Patent Literature 2 enables the magnetic skyrmion to be generated at the temperature higher than 27 K but fails to keep the generated magnetic skyrmion at the temperature higher than 27 K against the influence of thermal fluctuation. In an application of the magnetic element mounted on a magnetic device such as a discrete track medium that is used at the temperature higher than 27 K (for example, at 293±15 K that is ambient temperature specified by Japanese Industrial Standards), there is a demand for stably keeping the generated magnetic skyrmion at the temperature higher than 27 K.

A major object of the present disclosure is to provide a magnetic element that enables a generated magnetic skyrmion to be stably kept at a higher temperature, as well as to provide a magnetic device. A major object of a manufacturing method of a magnetic element is to manufacture a magnetic element that enables a generated magnetic skyrmion to be stably kept at a higher temperature.

In order to achieve the above primary aim, magnetic element, a magnetic device and a manufacturing method of the magnetic element of the present disclosure employs the following configuration.

The present disclosure is directed to a magnetic element, a magnetic device and a manufacturing method of the magnetic element. The magnetic element according to the present disclosure is formed from a magnetic material. The magnetic material is a material that is capable of generating a magnetic skyrmion. The defect is introduced at a position corresponding to each side of an approximate triangle in plan view.

In the magnetic element according to this aspect of the present disclosure, the magnetic material is the material that is capable of generating the magnetic skyrmion, and the defect is introduced at the position corresponding to each side of the approximate triangle in plan view. A magnetic field having such a direction and an intensity as to generate at least one magnetic skyrmion in an area corresponding to inside of the approximate triangle is applied to the magnetic element. This causes the magnetic skyrmion to be generated in the area corresponding to inside of the approximate triangle. This configuration enables the generated magnetic skyrmion to be stably kept at the higher temperature. This aspect accordingly provides the magnetic element that enables the magnetic skyrmion to be stably kept at the higher temperature.

The magnetic element according to the above aspect of the present disclosure, at least one magnetic skyrmion may be generated in an area corresponding to inside of the approximate triangle.

In the magnetic element according to any of the aspects of the present disclosure described above, a plurality of dot-like defects in plan view may be arrayed at intervals that are shorter than a diameter of the magnetic skyrmion to be generated, at the position corresponding to each side of the approximate triangle, so as to be arranged in a triangular shape as a whole. This configuration of forming a plurality of dot-like defects shortens the manufacturing time, compared with a configuration of forming a plurality of linear defects. This aspect accordingly provides the magnetic element that improves the throughput in manufacture.

In the magnetic element according to any of the aspects of the present disclosure described above, a linear defect in plan view may be provided at the position corresponding to each side of the approximate triangle, so as to be arranged in a triangular shape as a whole. The linear defects in plan view are formed at the positions corresponding to the respective sides of the approximate triangle, such as to be arranged in the triangular shape. This configuration accordingly enables the defects to be arranged at the positions corresponding to the respective sides of the approximate triangle in plan view.

In the magnetic element according to any of the aspects of the present disclosure described above, the defect may be either a concave or a convex formed in one face or may be a through hole. This configuration of forming the concave or the convex in one face or forming the through hole enables the defects to be introduced at the positions corresponding to the respective sides of the approximate triangle in plan view.

In the magnetic element according to any of the aspects of the present disclosure described above, the defect may be a different type of an atom different from an atom that is added to the magnetic material to constitute the magnetic material.

In the magnetic element according to any of the aspects of the present disclosure described above, a length of each side may be within a range of not less than √3 times and not greater than 5 times as large as a diameter of the magnetic skyrmion to be generated. This configuration enables one magnetic skyrmion or three magnetic skyrmions to be generated inside of the approximate triangle.

In the magnetic element according to any of the aspects of the present disclosure, the magnetic material may be a ferromagnetic metal. The magnetic material may be a metal having helimagnetism. The magnetic material may be a CoZnMn alloy. According to this aspect, the magnetic material may be formed to provide a (111) face that is parallel to the one face in crystal orientation. This configuration enables the magnetic skyrmion to be kept more stably at the higher temperature.

In the magnetic element according to any of the aspects of the present disclosure, the magnetic material may be a CoZnMn alloy, and a length of each side may be within a range of not less than 150 nm and not greater than 800 nm. This configuration enables one magnetic skyrmion or three magnetic skyrmions to be generated inside of the approximate triangle. In this case, the magnetic material may be formed to provide a (111) face that is parallel to the one face in crystal orientation. This configuration enables one magnetic skyrmion or three magnetic skyrmions to be kept inside of the approximate triangle more stably at the higher temperature.

According to another aspect of the present disclosure, there is provided a magnetic device comprising a plurality of the magnetic elements according to any of the aspects of the present disclosure. For example, the magnetic device comprises a plurality of magnetic elements formed from a magnetic material. The magnetic material is a material that is capable of generating a magnetic skyrmion, and a defect is introduced at a position corresponding to each side of an approximate triangle in plan view.

The magnetic device according to this aspect of the present disclosure comprises the magnetic elements according to any of the aspects of the present disclosure described above. Accordingly, the magnetic device of this aspect has advantageous effects similar to the advantageous effects of the magnetic element according to any of the above aspects of the present disclosure. For example, the magnetic device of this aspect has an advantageous effect of providing the magnetic element that enables the magnetic skyrmion to be kept stably at the higher temperature.

In the magnetic device according to this aspect of the present disclosure, the plurality of magnetic elements may be arranged such that the defect of each magnetic element is introduced at a position corresponding to each side of an approximate triangle and that the defect of each adjacent magnetic element is introduced at a position corresponding to each side of a 180-degree inverted approximate triangle. This configuration enables a larger number of magnetic elements to be arranged in a fixed area.

The magnetic device according to the above aspect of the present disclosure may be either a magnetic memory configured to store information or a magnetic sensor configured to detect magnetism or may be a discrete track medium.

The manufacturing method of a magnetic element according to the above aspect of the present disclosure is manufacturing method formed from a magnetic material that is capable of generating a magnetic skyrmion. The manufacturing method include a defect introducing process of introducing a defect into the magnetic material at a position corresponding to each side of an approximate triangle in plan view.

In the manufacturing method of the magnetic element according to this aspect of the present disclosure, the defect introducing process introduces the defect into the magnetic material at the position corresponding to each side of the approximate triangle in plan view. The manufacturing method of this aspect accordingly enables the magnetic element that is formed from the magnetic material capable of generating the magnetic skyrmion and that has the defect introduced at the position corresponding to each side of the approximate triangle in plan view to be manufactured. The magnetic element thus manufactured enables the generated magnetic skyrmion to be stably kept at the higher temperature. This aspect accordingly manufactures the magnetic element that enables the magnetic skyrmion to be stably kept at the higher temperature.

In the manufacturing method of the magnetic element according to this aspect of the present disclosure, the defect introducing process may comprise a process of introducing a plurality of dot-like defects in plan view into the magnetic material by using an electron beam. This configuration of forming a plurality of dot-like defects improves the throughput, compared with a configuration of forming a plurality of linear defects in plan view in the magnetic material.

### BRIEF DESCRIPTION OF DRAWINGS

FIG. 1 is a configuration diagram illustrating the schematic configuration of a magnetic device 10 according to one embodiment of the present disclosure;

FIG. 2 is an enlarged view illustrating the close-up of a portion A shown in FIG. 1;

FIG. 3 is an enlarged view illustrating the close-up of a portion B shown in FIG. 2;

FIG. 4 is a diagram illustrating one example of a scanning transmission electron microscope (STEM) image of a main part of the magnetic device 10 by the differential phase contrast (DPC) method under application of a magnetic field of 20 mT in a direction perpendicular to the surface S at a temperature of 300 K;

FIG. 5 is a diagram illustrating one example of a STEM image of the magnetic element 20 by the DPC method under application of a magnetic field of 20 mT in the direction perpendicular to the surface S at the temperature of 300 K;

FIG. 6 is a schematic diagram schematically illustrating the STEM image of FIG. 5;

FIG. 7 is a diagram illustrating one example of a STEM image of the magnetic element 20 by the DPC method under application of a magnetic field of 60 mT in the direction perpendicular to the surface S at the temperature of 300 K;

FIG. 8 is a diagram illustrating one example of a STEM image of a magnetic element 20B of a comparative example by the DPC method under application of a magnetic field of 20 mT in the direction perpendicular to the surface S at the temperature of 300 K;

FIG. 9 is a schematic diagram schematically illustrating the STEM image of FIG. 8;

FIG. 10 is a diagram illustrating one example of a STEM image of the magnetic element 20B of the comparative example by the DPC method under application of a magnetic field of 60 mT in the direction perpendicular to the surface S at the temperature of 300 K;

FIG. 11 is a schematic diagram schematically illustrating the STEM image of FIG. 10;

FIG. 12 is a diagram illustrating one example of a STEM image of a magnetic element 20C of another comparative example by the DPC method under application of a magnetic field of 20 mT in the direction perpendicular to the surface S at the temperature of 300 K;

FIG. 13 is a schematic diagram schematically illustrating the STEM image of FIG. 12;

FIG. 14 is a diagram illustrating one example of a STEM image of the magnetic element 20C of the comparative example by the DPC method under application of a magnetic field of 60 mT in the direction perpendicular to the surface S at the temperature of 300 K;

FIG. 15 is a schematic diagram schematically illustrating the STEM image of FIG. 14;

FIG. 16 is a flowchart showing one example of the manufacturing method of the magnetic device 10;

FIG. 17 is a diagram illustrating one example of the STEM image of the magnetic element 120 of the modification by the DPC method under application of a magnetic field of 60 mT in the direction perpendicular to the surface S at a temperature of 295 K; and

FIG. 18 is a diagram illustrating one example of the STEM image of the magnetic element 120 of the modification by the DPC method under application of a magnetic field of 20 mT in the direction perpendicular to the surface S at the temperature of 295 K.

### DESCRIPTION OF EMBODIMENTS

The following describes some aspects of the disclosure with reference to embodiments.

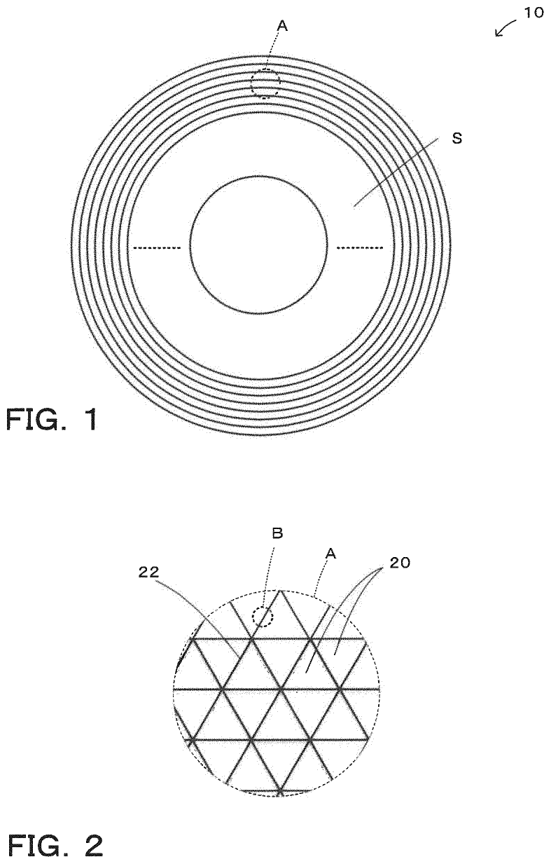

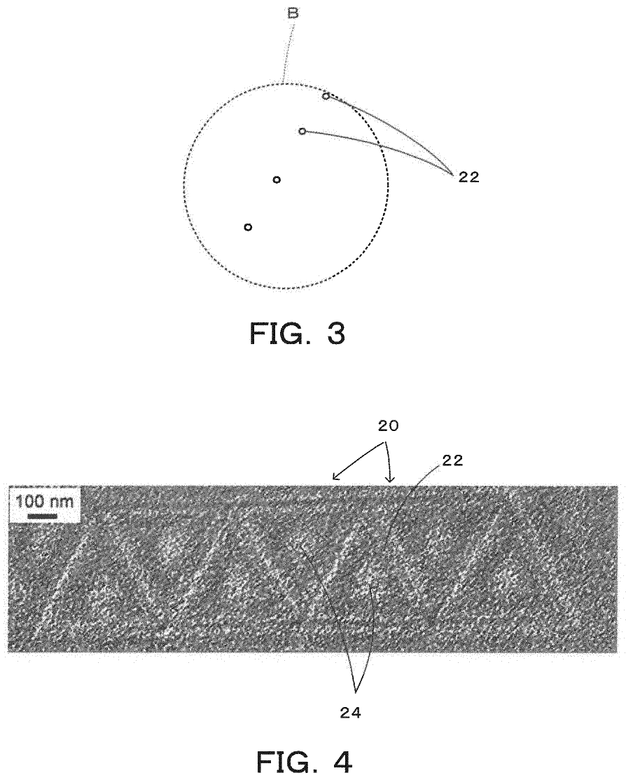

FIG. 1 is a configuration diagram illustrating the schematic configuration of a magnetic device 10 according to one embodiment of the present disclosure. FIG. 2 is an enlarged view illustrating the close-up of a portion A shown in FIG. 1. FIG. 3 is an enlarged view illustrating the close-up of a portion B shown in FIG. 2. The magnetic device 10 is configured as a discrete medium and has a plurality of magnetic elements 20 that are concentrically arranged on a bulk polycrystal substrate of Co₈Zn₈Mn₄ having a β-Mn crystal structure to form tracks.

The plurality of magnetic elements 20 are formed from Co₈Zn₈Mn₄ to have a thickness of 150 nm and provide a (111) face that is parallel to a surface S in crystal orientation. Co₈Zn₈Mn₄ is a magnetic alloy having helimagnetism. As shown in FIG. 2 and FIG. 3, the magnetic element 20 is configured to have a plurality of defects 22 that are dot-like concaves having a diameter of 2 nm in plan view and a depth of several nm (for example, 1 nm, 2 nm or 3 nm) and that are arranged at positions corresponding to respective sides of an approximate equilateral triangle of 440 nm on each side in plan view of the surface S to be arrayed at intervals of 10 nm. The plurality of magnetic elements 20 are arranged such that the defects 22 of each magnetic element 20 are introduced at positions corresponding to the respective sides of an approximate equilateral triangle and that the defects 22 of each adjacent magnetic element 20 are introduced at positions corresponding to the respective sides of a 180-degree inverted approximate equilateral triangle. In other words, the defects 22 are introduced such that the approximate equilateral triangles and the inverted approximate equilateral triangles are arranged alternately.

According to the embodiment, when a magnetic field of 20 mT to 80 mT is applied to the magnetic element 20 configured as described above at ambient temperature (for example, 300 K) in a direction perpendicular to the surface S (i.e., in a direction from the rear face toward the surface of illustrations in FIGS. 1 to 3), a magnetic skyrmion 24 is generated in an area corresponding to inside of the approximate equilateral triangle defined by the defects 22. FIG. 4 is a diagram illustrating one example of a scanning transmission electron microscope (STEM) image of a main part of the magnetic device 10 by the differential phase contrast (DPC) method under application of a magnetic field of 20 mT in a direction perpendicular to the surface S at a temperature of 300 K. The magnetic skyrmion 24 is generated in an approximately circular shape having a radius of 120 nm in plan view. This magnetic skyrmion 24 disappears by application of a magnetic field of larger than 80 mT. The magnetic device 10 can be operated as a memory by respectively mapping the state of generation of the magnetic skyrmion 24 and the state of disappearance of the magnetic skyrmion 24 to 1-bit information and detecting the magnetic field in the direction perpendicular to the surface S by means of a sensor such as a tunneling magneto resistance (TMR) element. An electron beam made to enter a sample by using an electron gun is deflected by a magnetic field generated inside of the sample. This causes a difference in intensities of the electron beam detected at respective positions by segmented detectors placed on the opposite side to the electron gun across the sample. The scanning transmission electron microscope (STEM) image by the differential phase contrast (DPC) method denotes a visualized image that visualizes the result of measurement of the magnetic field at respective points on the sample by utilizing such a difference.

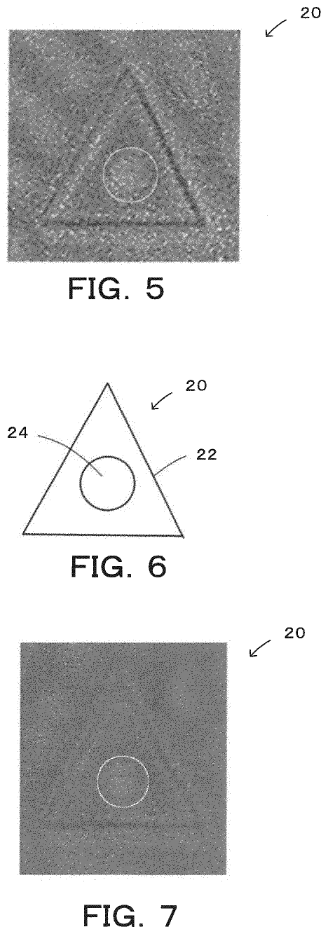

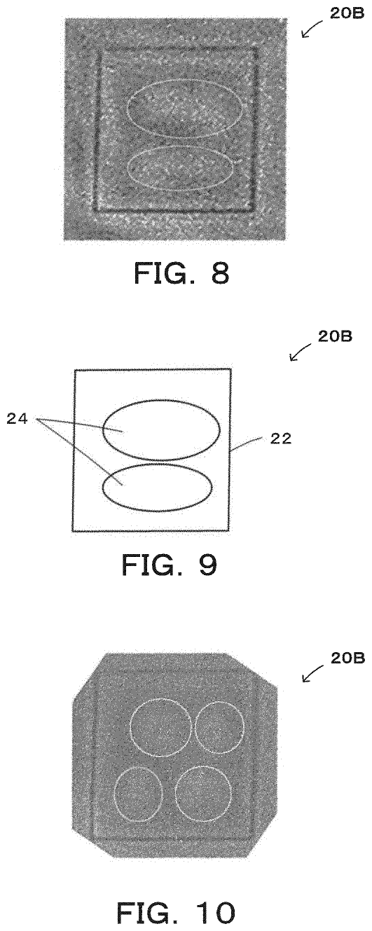

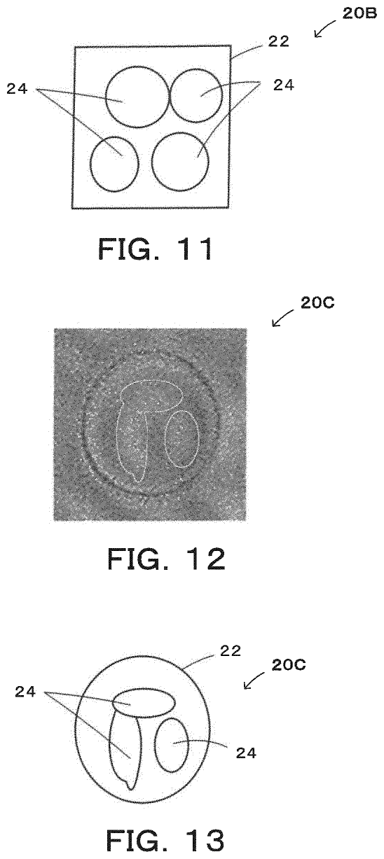

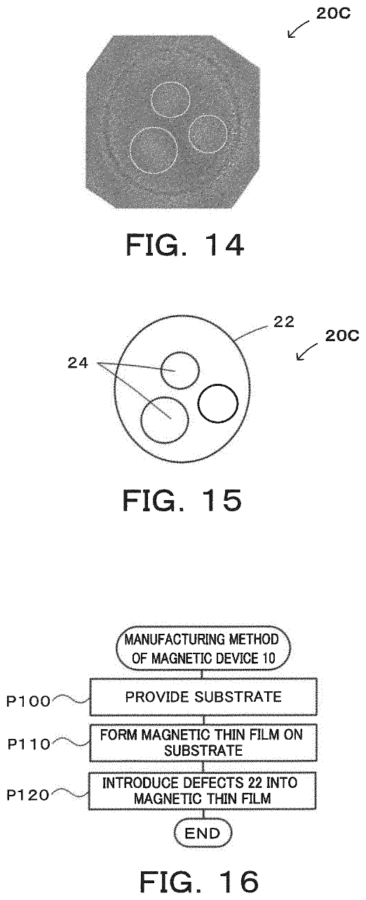

FIG. 5 is a diagram illustrating one example of a STEM image of the magnetic element 20 by the DPC method under application of a magnetic field of 20 mT in the direction perpendicular to the surface S at the temperature of 300 K. FIG. 6 is a schematic diagram schematically illustrating the STEM image of FIG. 5. FIG. 7 is a diagram illustrating one example of a STEM image of the magnetic element 20 by the DPC method under application of a magnetic field of 60 mT in the direction perpendicular to the surface S at the temperature of 300 K. A schematic diagram that schematically illustrates the STEM image of FIG. 7 is substantially similar to the schematic diagram of FIG. 6 and is not specifically provided. FIG. 8 is a diagram illustrating one example of a STEM image of a magnetic element 20B of a comparative example by the DPC method under application of a magnetic field of 20 mT in the direction perpendicular to the surface S at the temperature of 300 K. FIG. 9 is a schematic diagram schematically illustrating the STEM image of FIG. 8. FIG. 10 is a diagram illustrating one example of a STEM image of the magnetic element 20B of the comparative example by the DPC method under application of a magnetic field of 60 mT in the direction perpendicular to the surface S at the temperature of 300 K. FIG. 11 is a schematic diagram schematically illustrating the STEM image of FIG. 10. FIG. 12 is a diagram illustrating one example of a STEM image of a magnetic element 20C of another comparative example by the DPC method under application of a magnetic field of 20 mT in the direction perpendicular to the surface S at the temperature of 300 K. FIG. 13 is a schematic diagram schematically illustrating the STEM image of FIG. 12. FIG. 14 is a diagram illustrating one example of a STEM image of the magnetic element 20C of the comparative example by the DPC method under application of a magnetic field of 60 mT in the direction perpendicular to the surface S at the temperature of 300 K. FIG. 15 is a schematic diagram schematically illustrating the STEM image of FIG. 14. The magnetic element 20B of the comparative example is an element with defects introduced at positions corresponding to respective sides of an approximate square in plan view of the surface S. The magnetic element 20C of the comparative example is an element with defects introduced at positions corresponding to a circumference of an approximate circle in plan view of the surface S. Magnetic skyrmions are generated in white encircled areas in the illustrations of FIG. 5, FIG. 6, FIG. 8, FIG. 10, FIG. 12 and FIG. 14.

As shown in FIG. 5 and FIG. 6, in the magnetic element 20 of the embodiment, irrespective of a variation in the magnetic field applied, one magnetic skyrmion in an approximately circular shape is stably generated in an area corresponding to inside of the approximate triangle in plan view. In the magnetic element 20B of the comparative example, on the other hand, a variation in the magnetic field applied varies the shape and the number of magnetic skyrmions generated in an area corresponding to inside of the approximate square in plan view. In the magnetic element 20C of the comparative example, a variation in the magnetic field applied varies the number of magnetic skyrmions generated in an area corresponding to inside of the approximate circle in plan view. As clearly understood from the foregoing, the magnetic element 20 of the embodiment enables the magnetic skyrmion to be stably kept at the higher temperature or more specifically at ambient temperature (for example, at 293±15 K that is ambient temperature specified by Japanese Industrial Standards), compared with the magnetic elements 20B and 20C of the comparative examples.

The following describes a manufacturing method of the magnetic device 10 having the configuration described above. FIG. 16 is a flowchart showing one example of the manufacturing method of the magnetic device 10.

The manufacturing method first provides a substrate that is suitable for crystal growth of Co₈Zn₈Mn₄ (process P100). The substrate provided may be a silicon (Si) substrate.

The manufacturing method subsequently forms a magnetic thin film of Co₈Zn₈Mn₄ on the substrate (process P110). More specifically, the process P110 forms the magnetic thin film of Co₈Zn₈Mn₄ on the substrate to provide a (111) face that is parallel to the surface S by using a technique such as MBE (molecular beam epitaxy) method.

The manufacturing method then forms concaves on the surface of the magnetic thin film to introduce defects 22 into the magnetic thin film (process P120) and thereby completes the magnetic device 10. More specifically, the process P120 forms a plurality of defects 22 that are dot-like concaves having a diameter of 2 nm in plan view to be arrayed at intervals of 10 nm at positions corresponding to respective sides of an approximate equilateral triangle of 440 nm on each side in plan view of the surface S, by using an electron beam from a Schottky field emission electron gun operating at 200 kV. The manufacturing method sequentially forms a plurality of the magnetic elements 20, such that the defects 22 of each magnetic element 20 are introduced at positions corresponding to the respective sides of an approximate equilateral triangle and that the defects 22 of each adjacent magnetic element 20 are introduced at positions corresponding to the respective sides of a 180-degree inverted approximate equilateral triangle. This process forms the dot-like concaves as the defects 22. Compared with a process of forming linear concaves as the defects 22, this process effectively shortens the time period required for forming the defects 22. This improves the throughput of formation of the magnetic elements 20 and thereby improves the throughput of manufacture of the magnetic device 10.

As described above, the magnetic device 10 of the embodiment enables the generated magnetic skyrmions 24 to be stably kept at the higher temperature by introducing the defects 22 into the magnetic material that allows for generation of the magnetic skyrmions 24, at the positions corresponding to the respective sides of the approximate triangle in plan view.

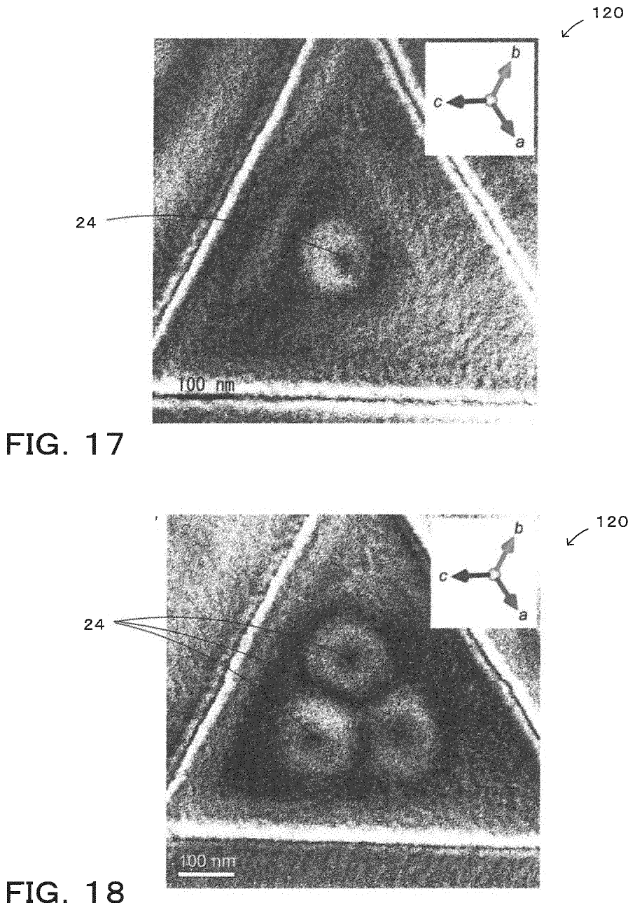

In the magnetic device 10 of the embodiment, one magnetic skyrmion 24 is generated in the area corresponding to inside of the approximate triangle in plan view of the magnetic element 20. One modification may generate two or more magnetic skyrmions 24 by changing the length of each side of the approximate triangle. FIG. 17 and FIG. 18 are diagrams illustrating examples of a STEM image of a magnetic element 120 of a modification by the DPC method. In the magnetic element 120 of the modification, a plurality of defects 22 that are dot-like concaves having a diameter of 5 nm in plan view are formed to be arrayed at intervals of 10 nm at positions corresponding to respective sides of an approximate equilateral triangle of 800 nm on each side in plan view of the surface S.

FIG. 17 is a diagram illustrating one example of the STEM image of the magnetic element 120 of the modification by the DPC method under application of a magnetic field of 60 mT in the direction perpendicular to the surface S at a temperature of 295 K. FIG. 18 is a diagram illustrating one example of the STEM image of the magnetic element 120 of the modification by the DPC method under application of a magnetic field of 20 mT in the direction perpendicular to the surface S at the temperature of 295 K. As shown in FIG. 17, in the magnetic element 120, one magnetic skyrmion 24 is generated in an area corresponding to inside of the approximate equilateral triangle under application of the magnetic field of 60 mT in the direction perpendicular to the surface S. As shown in FIG. 18, in the magnetic element 120, three magnetic skyrmions 24 are generated in the area corresponding to inside of the approximate equilateral triangle under application of the magnetic field of 20 mT in the direction perpendicular to the surface S. In the magnetic element 120, the number of magnetic skyrmions generated changes from three to one with an increase in the intensity of the applied magnetic field from 20 mT to approximately 40 mT (40 mT±1.0 mT). When the magnetic field applied has the intensity of higher than 77 mT, the magnetic skyrmion becomes unstable or disappears in the magnetic element 120. Accordingly, in the magnetic element 120, each of the state that one magnetic skyrmion 24 is generated, the state that three magnetic skyrmions 24 are generated, and the state that the magnetic skyrmion 24 disappears is mapped to one bit, and the magnetic filed in the direction perpendicular to the surface S is detected by a sensor such as a tunneling magneto resistance (TMR) element. This configuration enables a magnetic device 110 of the modification including a plurality of the magnetic elements 120 to be operated as a memory.

In the magnetic device 10 of the embodiment, the defects 22 that are a plurality of dot-like concaves in plan view are introduced into the magnetic material. The requirement is, however, that some defects are introduced into the magnetic material at positions corresponding to respective sides of an approximate equilateral triangle in plan view. One modification may introduce defects that are convexes into the magnetic material, in place of the plurality of dot-like concaves. Another modification may introduce linear defects into the magnetic material at the positions corresponding to the respective sides of the approximate equilateral triangle in plan view. Another modification may form through holes in the magnetic material at the positions corresponding to the respective sides of the approximate equilateral triangle in plan view. Another modification may introduce a different type of atoms that is different from the type of atoms constituting the magnetic material, into the magnetic material at the positions corresponding to the respective sides of the approximate equilateral triangle in plan view.

In the magnetic device 10 of the embodiment, the defects 22 are introduced at the positions corresponding to the respective sides of the approximate equilateral triangle of 440 nm on each side in plan view of the surface S of the magnetic element 20. The length of the respective sides of the approximate equilateral triangle may, however, be any length within a range of not less than √3 times and not greater than 5 times as large as the diameter of the magnetic skyrmion that is generated in the area corresponding to inside of the approximate equilateral triangle.

In the magnetic device 10 of the embodiment, the defects 22 are introduced at the positions corresponding to the respective approximate equilateral triangle in plan view of the surface S of the magnetic element 20. The approximate equilateral triangle is, however, not essential but may be replaced with an approximate isosceles triangle having two sides of approximately equal lengths or with an approximate triangle having three sides of different lengths.

In the magnetic device 10 of the embodiment, the magnetic element 20 is formed from Co₈Zn₈Mn₄. Any material that is capable of generating the magnetic skyrmion may, however, be used as the material used to form the magnetic element 20. The material used to form the magnetic element 20 may be a helimagnetic material having a B20 crystal structure. Examples of the “helimagnetic material having the B20 crystal structure” include MnSi, MnGe, MnGeFe, FeGe, FeGeSi, FeCoSi and Cu₂OSeO₃. Furthermore, the magnetic element 20 may be configured to have a layered structure of a magnetic thin film and a metal that is capable of generating the magnetic skyrmion. Examples of the material of the “magnetic thin film” include Fe, Co and Ni. Examples of the “metal” include Pt, Ir and W. The magnetic element 20 may be formed from a polar magnetic semiconductor. Examples of the “polar magnetic semiconductor” include GaV₄S₈ and GaV₄Se₈.

In the magnetic device 10 of the embodiment, the magnetic element 20 is formed from Co₈Zn₈Mn₄. The magnetic element 20 may, however, be formed from any other ferromagnetic metal.

In the magnetic device 10 of the embodiment, the magnetic material used is Co₈Zn₈Mn₄ having helimagnetism. The magnetic material used may, however, be any other magnetic material that is capable of generating the magnetic skyrmion and may be a magnetic material having different magnetism from helimagnetism.

In the magnetic device 10 of the embodiment, the magnetic element 20 is configured such that the magnetic material provides the (111) face that is parallel to the surface S in crystal orientation. Any other magnetic material that is capable of generating the magnetic skyrmion may, however, be used to provide a different face that is different from the (111) face and that is parallel to the surface S in crystal orientation.

In the magnetic device 10 of the embodiment, the plurality of magnetic elements 20 are arranged such that the defects 22 of each magnetic element 20 are introduced at the positions corresponding to the respective sides of the approximate triangle and that the defects 22 of each adjacent magnetic element 20 are introduced at the positions corresponding to the respective sides of the 180-degree inverted approximate triangle. According to a modification, the plurality of magnetic elements 20 may be arranged such that the defects 22 of each magnetic element 20 are introduced at the positions corresponding to the respective sides of an approximate triangle and that the defects 22 of each adjacent magnetic element 20 are introduced at the positions corresponding to the respective sides of an adjacent approximate triangle.

The above embodiment illustrates the aspect of the present disclosure applied to the discrete track medium. Another aspect of the present disclosure may be applicable to any magnetic memory configured to store information. Another aspect of the present disclosure may also be applicable to a magnetic sensor configured to detect the magnetism.

The aspect of the disclosure is described above with reference to the embodiment. The disclosure is, however, not limited to the above embodiment but various modifications and variations may be made to the embodiment without departing from the scope of the disclosure.

The technique of the disclosure is preferably applicable to the manufacturing industries of the magnetic element and the magnetic device and so on.

1. A magnetic element formed from a magnetic material,
wherein the magnetic material is a material that is capable of generating a magnetic skyrmion, and
a defect is introduced at a position corresponding to each side of an approximate triangle in plan view.

2. The magnetic element according to claim 1,
wherein at least one magnetic skyrmion is generated in an area corresponding to inside of the approximate triangle.

3. The magnetic element according to claim 1,
wherein a plurality of dot-like defects in plan view are arrayed at intervals that are shorter than a diameter of the magnetic skyrmion to be generated, at the position corresponding to each side of the approximate triangle, so as to be arranged in a triangular shape as a whole.

4. The magnetic element according to claim 1,
wherein a linear defect in plan view is provided at the position corresponding to each side of the approximate triangle, so as to be arranged in a triangular shape as a whole.

5. The magnetic element according to claim 1,
wherein the defect is either a concave or a convex formed in one face.

6. The magnetic element according to claim 1,
wherein the defect is a through hole.

7. The magnetic element according to claim 1,
wherein the defect is a different type of an atom different from an atom that is added to the magnetic material to constitute the magnetic material.

8. The magnetic element according to claim 1,
wherein a length of each side is within a range of not less than √β times and not greater than 5 times as large as a diameter of the magnetic skyrmion to be generated.

9. The magnetic element according to claim 1,
wherein the magnetic material is a ferromagnetic metal.

10. The magnetic element according to claim 1,
wherein the magnetic material is a metal having helimagnetism.

11. The magnetic element according to claim 1,
wherein the magnetic material is a CoZnMn alloy.

12. The magnetic element according to claim 1,
wherein the magnetic material is a CoZnMn alloy, and
a length of each side is within a range of not less than 150 nm and not greater than 800 nm.

13. The magnetic element according to claim 11,
wherein the magnetic material is formed to provide a (111) face that is parallel to the one face in crystal orientation.

14. A magnetic device comprising a plurality of magnetic elements formed from a magnetic material,
wherein the magnetic material is a material that is capable of generating a magnetic skyrmion, and
a defect is introduced at a position corresponding to each side of an approximate triangle in plan view.

15. The magnetic device according to claim 14,
wherein the plurality of magnetic elements are arranged such that the defect of each magnetic element is introduced at a position corresponding to each side of an approximate equilateral triangle and that the defect of each adjacent magnetic element is introduced at a position corresponding to each side of a 180-degree inverted approximate equilateral triangle.

16. The magnetic device according to claim 14,
the magnetic device being either a magnetic memory configured to store information or a magnetic sensor configured to detect magnetism.

17. The magnetic device according to claim 14,
the magnetic device being a discrete track medium.

18. A manufacturing method of a magnetic element formed from a magnetic material that is capable of generating a magnetic skyrmion,
the manufacturing method comprising:
a defect introducing process of introducing a defect into the magnetic material at a position corresponding to each side of an approximate triangle in plan view.

19. The manufacturing method of the magnetic element according to claim 18,
wherein the defect introducing process comprises a process of introducing a plurality of dot-like defects in plan view into the magnetic material by using an electron beam.
